(19) United States
(12) Patent Application Publication
(10) Pub. No.: US 2016/0102396 A1
(43) Pub. Date: Apr. 14, 2016

(54) PHYSICAL VAPOR DEPOSITION APPARATUS AND METHOD OF DEPOSITING PHASE-CHANGE MATERIALS USING THE SAME

(71) Applicant: Samsung Electronics Co., Ltd., Suwon-si (KR)

(72) Inventors: Zhe Wu, Suwon-si (KR); Jung-Hwan Park, Seoul (KR); Jeong-Hee Park, Hwaseong-si (KR); Dong-Ho Ahn, Hwaseong-si (KR)

(21) Appl. No.: 14/876,183

(22) Filed: Oct. 6, 2015

(30) Foreign Application Priority Data
Oct. 10, 2014 (KR) 10-2014-0136652

(51) Int. Cl. C23C 14/54; C23C 14/14; C23C 14/50; C23C 14/22

(52) U.S. Cl. CPC C23C 14/541; C23C 14/228; C23C 14/14; C23C 14/50; C23C 14/542; C23C 14/548

(57) ABSTRACT

A physical vapor deposition (PVD) apparatus for forming a phase-changeable layer includes a process chamber including a loading chamber configured to load a substrate, and a depositing chamber configured to deposit ion particles of a phase-changeable material onto the substrate; a target member on an upper portion of the depositing chamber and configured to provide the ion particles of the phase-changeable material which react with process gases in a plasma state; a plasma generator configured to generate a process gas plasma from the process gases; a chuck on a lower portion of the depositing chamber and holding the substrate, the chuck including a heater configured to heat the substrate, and at least one electrode configured to guide the ion particles of the phase-changeable material to the substrate; and a supplementary heater in the process chamber and configured to transfer radiant heat around the substrate.

### CROSS-REFERENCE TO RELATED APPLICATIONS

This application claims under 35 U.S.C. §119 to Korean Patent Application No. 10-2014-0136652 filed on Oct. 10, 2014 in the Korean Intellectual Property Office, the disclosure of which is incorporated by reference herein in its entirety.

### BACKGROUND

1. Field

Example embodiments relate to a physical vapor deposition (PVD) apparatus and a method of depositing phase-change materials using the same, and more particularly, to a PVD apparatus for depositing phase-change materials using plasma and a method of depositing phase-change materials onto a substrate using the same.

2. Description of the Related Art

A resistive nonvolatile memory device has advantages in that the erasing operation is not needed and the programming operation is simple and easy, so the resistive nonvolatile memory device has been developed in view of simplification of electronic systems. For example, a phase-changeable random access memory (PRAM), a resistive RAM (RRAM) and a magnetic RAM (MRAM) have been intensively studied as the next generation nonvolatile memory device.

While a conventional nonvolatile memory device such as flash memory devices programs or erases data by storing the electronic charges, the resistive nonvolatile memory device programs or erases data by changing electrical resistance of variable resistors.

The electrical resistance of the variable resistor of the PRAM device is clearly changed between the phases of the resistor materials, e.g., between crystalline phase and the amorphous phase of the resistor materials. Thus, the PRAM necessarily includes a resistor of which the electrical resistance is changed by the phase of the phase-changeable material and storing electronic data in response to the change of the resistance as a memory cell and a switching element for accessing the electronic data of the resistor.

The phase-changeable material is deposited onto a substrate by a physical vapor deposition (PVD) process in plasma state, and requires characteristics of relatively high vapor pressure and low vaporization heat. For that reason, a compound of germanium (Ge), antimony (Sb) and tellurium (Te), which is called as GST, is most widely used as the phase-changeable material of the PRAM.

However, when the temperature of peripheral portion is different from that of the central portion of the substrate, the composition and the thickness of the GST layer may be different between the central portion and the peripheral portion of the substrate due to the differences of the evaporation heat of the deposition materials.

### SUMMARY

Example embodiments of the present inventive concepts provide a PVD apparatus having an additional heater for providing radiant heat to a peripheral portion of a substrate.

Example embodiments of the present inventive concepts provide a method of depositing phase-changeable materials onto the substrate using the above PVD apparatus.

According to example embodiments of the inventive concepts, a PVD apparatus includes a process chamber including a loading chamber configured to load a substrate, and a depositing chamber configured to deposit ion particles of a phase-changeable material onto the substrate, a target member on an upper portion of the depositing chamber and configured to provide the ion particles of the phase-changeable material which react with process gases in a plasma state, a plasma generator configured to generate a process gas plasma from the process gases, a chuck on a lower portion of the depositing chamber and holding the substrate, the chuck including a heater configured to heat the substrate and at least one electrode configured to guide the ion particles of the phase-changeable material to the substrate, and a supplementary heater in the process chamber and configured to transfer radiant heat around the substrate.

In example embodiments, the supplementary heater may be in the loading chamber and spaced apart in a downward vertical direction from a peripheral portion of a bottom surface of the chuck.

In example embodiments, the supplementary heater may be a ring-shaped electrical lamp surrounding the chuck.

In example embodiments, the supplementary heater may be a ring-shaped tube surrounding the chuck and configured to allow a fluid to flow therethrough.

In example embodiments, the PVD apparatus may further include a heat shielding member concavely connected to a sidewall and a bottom surface of the loading chamber and defining a first space inside the loading chamber.

In example embodiments, the supplementary heater may be in the depositing chamber and spaced apart in an upward vertical direction from a peripheral portion of a top surface of the chuck.

In example embodiments, the supplementary heater may be a ring-shaped electrical lamp surrounding the chuck.

In example embodiments, the PVD apparatus may further include a heat shielding member concavely connected to a sidewall and a bottom surface of the depositing chamber and defining a second space inside the depositing chamber.

In example embodiments, the PVD apparatus may further include a holder secured to a bottom surface of the depositing chamber and configured to secure the substrate to the chuck, wherein the supplementary heater may include an electrical heating body inside the holder.

In example embodiments, the holder may be shaped into a ring covering a peripheral portion of the substrate and the electrical heating body may be arranged along the peripheral portion of the substrate in the holder.

In example embodiments, the holder may be configured to mechanically connect the substrate to the chuck.

In example embodiments, the phase-changeable material may include one of germanium (Ge), tellurium (Te), antimony (Sb) and combinations thereof.

In example embodiments, the PVD apparatus may further include a process gas supplier connected to the depositing chamber and configured to supply the process gases thereto, a first power source configured to supply power to the supplementary heater, a second power source configured to supply electrical power to the heater and the at least one electrode, and a controller connected to the process gas supplier, the plasma generator, the first power source and the second power source and configured to control a physical vapor deposition process for forming the phase-changeable layer on the substrate in the process chamber.

In example embodiments, the controller may selectively operate the first power source in accordance with the phase-changeable material in order to selectively operate the supplementary heater in accordance with the phase-changeable material.

In example embodiments, the PVD apparatus may further include a magnet over the target member and configured to control a density of the process gas plasma in the depositing chamber.

According to example embodiments of the inventive concepts, a physical vapor deposition (PVD) apparatus for forming a phase-changeable layer includes a process chamber including a substrate loaded therein, a target member on an upper portion of the process chamber, the target member configured to deposit ion particles of a phase-changeable material onto the substrate, an electronic speed controller on a lower portion of the process chamber, the electronic speed controller holding the substrate and configured to guide the ion particles of the phase-changeable material to the substrate, and a heat dissipating ring in the process chamber, the heat dissipating ring encircling the electronic speed controller and configured to transfer radiant heat around the substrate.

In example embodiments, the PVD apparatus may further include a heat reflector concavely connected to a sidewall and a bottom surface of the process chamber, the heat reflector defining a space inside the process chamber.

In example embodiments, the heat dissipating ring may be spaced apart in a downward vertical direction from a peripheral portion of a bottom surface of the electronic speed controller.

In example embodiments, the heat dissipating ring may be spaced apart in an upward vertical direction from a peripheral portion of a top surface of the electronic speed controller.

In example embodiments, the PVD apparatus may further include a process gas supplier connected to the process chamber, the process gas supplier configured to supply process gases to the process chamber, a plasma generator configured to generate a process gas plasma from the process gases, the process gas plasma reacting with the ion particles of the phase-changeable material, and a magnet over the target member, the magnet configured to control a density of the process gas plasma in the process chamber.

According to example embodiments of the present inventive concepts, when the evaporation heat of the phase-changeable material is relatively small and the deposition temperature for the PVD process is relatively high, the additional heat may be supplied to the process chamber and thus the temperature deviation of the substrate may be sufficiently reduced in the deposition process. Accordingly, the composition and the thickness of the phase-changeable layer may be sufficiently uniform across the whole surface of the substrate.

In addition, the evaporation amount of the phase-changeable material may be more easily controlled just by controlling the process temperature of the depositing chamber, thereby more easily controlling the composition and thickness of the phase-changeable layer.

### BRIEF DESCRIPTION OF THE DRAWINGS

These and other features of the inventive concepts will become more apparent by describing in detail example embodiments thereof with reference to the accompanying drawings of which:

FIG. 1 is a cross-sectional view illustrating a physical vapor deposition (PVD) apparatus in accordance with example embodiments of the present inventive concepts;

FIG. 2 is a cross-sectional view illustrating the chuck of the PVD apparatus shown in FIG. 1;

FIG. 3A is a cross-sectional view of an example embodiment of the supplementary heater of the PVD apparatus shown in FIG. 1;

FIG. 3B is a plan view of the example embodiment of the supplementary heater shown in FIG. 3A;

FIGS. 4A and 4B are plan views illustrating the modifications of the example embodiment of the supplementary heater shown in FIGS. 3A and 3B;

FIG. 5A is a cross-sectional view of an example embodiment of the supplementary heater of the PVD apparatus shown in FIG. 1;

FIG. 5B is a plan view of the example embodiment of the supplementary heater shown in FIG. 5A;

FIG. 6A is a cross-sectional view of an example embodiment of the supplementary heater of the PVD apparatus shown in FIG. 1;

FIG. 6B is a plan view of the example embodiment of the supplementary heater shown in FIG. 6A;

FIG. 7 is a flow chart showing a method of forming a phase-changeable layer on a substrate in the PVD apparatus shown in FIG. 1; and

FIG. 8 is a flow chart showing the step of preparing the deposition process shown in FIG. 7.

### DETAILED DESCRIPTION

Example embodiments will now be described more fully with reference to the accompanying drawings. Embodiments, however, may be embodied in many different forms and should not be construed as being limited to the embodiments set forth herein. Rather, these example embodiments are provided so that this disclosure will be thorough and complete, and will fully convey the scope to those skilled in the art. In the drawings, the thicknesses of layers and regions may be exaggerated for clarity.

It will be understood that when an element is referred to as being “on,” “connected to,” “electrically connected to,” or “coupled to” to another component, it may be directly on, connected to, electrically connected to, or coupled to the other component or intervening components may be present. In contrast, when a component is referred to as being “directly on,” “directly connected to,” “directly electrically connected to,” or “directly coupled to” another component, there are no intervening components present. As used herein, the term “and/or” includes any and all combinations of one or more of the associated listed items.

It will be understood that although the terms first, second, third, etc., may be used herein to describe various elements, components, regions, layers, and/or sections, these elements, components, regions, layers, and/or sections should not be limited by these terms. These terms are only used to distinguish one element, component, region, layer, and/or section from another element, component, region, layer, and/or section. For example, a first element, component, region, layer, and/or section could be termed a second element, component, region, layer, and/or section without departing from the teachings of example embodiments.

Spatially relative terms, such as “beneath,” “below,” “lower,” “above,” “upper,” and the like may be used herein for ease of description to describe the relationship of one component and/or feature to another component and/or feature, or other component(s) and/or feature(s), as illustrated in the drawings. It will be understood that the spatially relative terms are intended to encompass different orientations of the device in use or operation in addition to the orientation depicted in the figures.

The terminology used herein is for the purpose of describing particular example embodiments only and is not intended to be limiting of example embodiments. As used herein, the singular forms “a,” “an,” and “the” are intended to include the plural forms as well, unless the context clearly indicates otherwise. It will be further understood that the terms “comprises,” “comprising,” “includes,” and/or “including,” when used in this specification, specify the presence of stated features, integers, steps, operations, elements, and/or components, but do not preclude the presence or addition of one or more other features, integers, steps, operations, elements, components, and/or groups thereof.

Example embodiments may be described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will typically have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature, their shapes are not intended to illustrate the actual shape of a region of a device, and their shapes are not intended to limit the scope of the example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

Reference will now be made to example embodiments, which are illustrated in the accompanying drawings, wherein like reference numerals may refer to like components throughout.

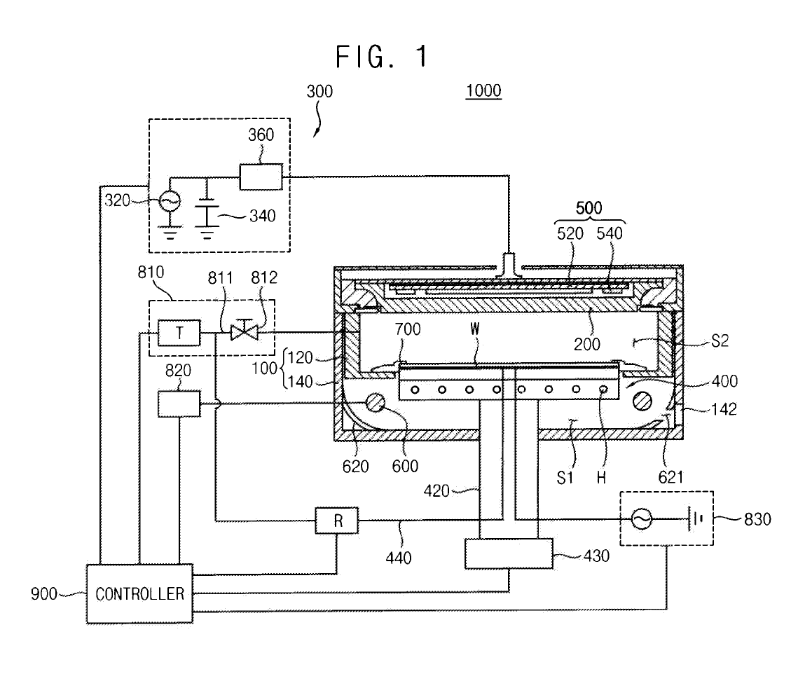

FIG. 1 is a cross-sectional view illustrating a physical vapor deposition (PVD) apparatus in accordance with example embodiments of the present inventive concepts.

Referring to FIG. 1, the PVD apparatus 1000 in accordance with example embodiments of the present inventive concepts may include a process chamber 100 for depositing a phase-changeable material onto a substrate W, a target member 200 for providing ion particles of the phase-changeable material, a plasma generator 300 for changing process gases into a plasma state, thereby generating a process gas plasma, a chuck 400 for holding the substrate in the deposition process and a supplementary heater 600 for selectively supplying a radiant heat around the chuck 400 in the deposition process.

The process chamber 100 may be isolated from surroundings under relatively high temperature and pressure in the deposition process. In the present example embodiment, the process chamber 100 may include a depositing chamber 120 for performing the physical vapor deposition (PVD) process and a loading chamber 140 under the depositing chamber 120 and to which the substrate W may be loaded for the PVD process. The loading chamber 140 may be arranged under the depositing chamber 120 and may be communicated with the depositing chamber 120. Particularly, the loading chamber 140 may be arranged in one body together with a housing (not shown) of the process chamber 100.

The depositing chamber 120 may include sidewalls and a bottom surface that may define an inner space thereof. A first gate (not shown) may be prepared with the bottom surface of the depositing chamber 120 through the depositing chamber 120 may be communicated with the loading chamber 140. Thus, the chuck 400 may move upwards and downwards between the depositing chamber 120 and the loading chamber 140 through the first gate.

The target member 200 and the plasma generator 300 may be arranged at an upper portion of the depositing chamber 120. Therefore, the inner space of the depositing chamber 120, hereinafter referred to as second space S2, may be defined by the sidewalls, the bottom surface having the first gate and the target member 200 and the plasma generator 300.

A process gas supplier 810 may be arranged around the depositing chamber 120. The process gases in a source tank T may be supplied to the second space S2 via a supply tube 811 that may be controlled by a supply valve 812. Thereafter, the process gases may be changed into a plasma state by the plasma generator 300, so that the process gases may be generated into the process gas plasma in the depositing chamber 120.

Although not shown in figures, a control pump and a plurality of discharge lines may be further arranged to the depositing chamber 120. A deposition pressure may be applied to the depositing chamber 120 in the PVD process by the control pump and byproducts of the PVD process may be discharged out of the depositing chamber 120 through the discharge lines. In the present example embodiment, the depositing chamber 120 may be under the deposition pressure of about 13 mTorr to about 75 mTorr, and more particularly, about 40 mTorr and to about 75 mTorr.

The loading chamber 140 may include sidewalls and a bottom surface that may define an inner space thereof and may be positioned below the depositing chamber 120. Thus, the inner space of the loading chamber 140, hereinafter referred to as second space S2, may be covered with the bottom surface of the depositing chamber 120. That is, the second space S2 may be defined by the bottom surface of the depositing chamber 120 and the sidewalls and the bottom surface of the loading chamber 140. The sidewalls and the bottom surface of the loading chamber 140 may function as the housing of the process chamber 100, so that the features of the process chamber 100 may be defined by the sidewalls and the bottom surface of the loading chamber 140.

A second gate 142 may be arranged at the sidewall of the loading chamber 140 and the substrate W may be loaded into the loading chamber 140 through the second gate 142. A penetration hole may be arranged at the bottom surface of the loading chamber 140 and a rotating shaft 420 of the chuck 400 may be arranged through the penetration hole of the bottom surface of the loading chamber 140.

Accordingly, the process chamber 100 may include an inner space defined by the housing (not shown) and the depositing chamber 120 may be arranged at an upper portion of the inner space of the process chamber 100 and the loading chamber 140 may be arranged at a lower portion of the inner space of the process chamber 100. The substrate W may be loaded into the loading chamber 140 and then the substrate may be elevated upward into the depositing chamber 120. The phase-changeable material may be deposited onto the substrate W in the depositing chamber 120.

The target member 200 may be arranged at the upper portion of the depositing chamber 120 and thus may define the second space S2 together with the sidewalls and the bottom surface of the depositing chamber 120. The target member 200 may provide ion particles of the phase-changeable material to react with the process gas plasma. Examples of the phase-changeable material may include germanium (Ge), tellurium (Te) and antimony (Sb). These may be used alone or in combinations thereof. The target member 200 may have shapes and configurations similar to those of the substrate W and may face the substrate W on the chuck 400.

The plasma generator 300 may be connected to the target member 200 and may include a first power supplier 320 for applying a relatively high frequency alternating current (AC) power to the target member 200 and a second power supplier 340 for applying a direct current (DC) power to the target member 200. A plasma impedance may be applied to the first power supplier 320 and may be matched into a transmission path impedance by a matching device 360. Then, the transmission path impedance may be applied to an upper electrode (not shown) that may be connected to the target member 200. For example, the first power supplier 320 may generate the AC power of about 5 KW to about 10 KW having the relatively high frequency of about 60 MHz to about 100 MHz. The second power supplier 340 may generate the DC power of about 6 KW to about 12 KW. The process gases may include inactive gases such as a helium (He) gas and an argon (Ar) gas.

The target member 200 may react with the process gas plasma in the depositing chamber 120 and the phase-changeable material may be generated from the target member 200 as the ion particles. The ion particles of the phase-changeable material may be guided onto the substrate W by the electrode E of the chuck 400 and may be deposited to the substrate W. The electrode E of the chuck 400 may be sometimes referred to as a lower electrode in comparison with the upper electrode.

The chuck 400 may be rotatable and may move upwards and downwards. When the chuck 400 may be located at a standby position in the loading chamber 140, the substrate W may be loaded onto the chuck 400 through the second gate 142 and then the substrate W may be secured to a top surface of the chuck 400. Thereafter, the chuck 400 may move upwards into the depositing chamber 120. When completing the deposition process to the substrate W in the depositing chamber 120, the chuck 400 may move downwards again into the loading chamber 140 and may be located at the same standby position. Then, the substrate W on which the phase-changeable layer may be formed may be unloaded from the loading chamber 140 through the second gate 142.

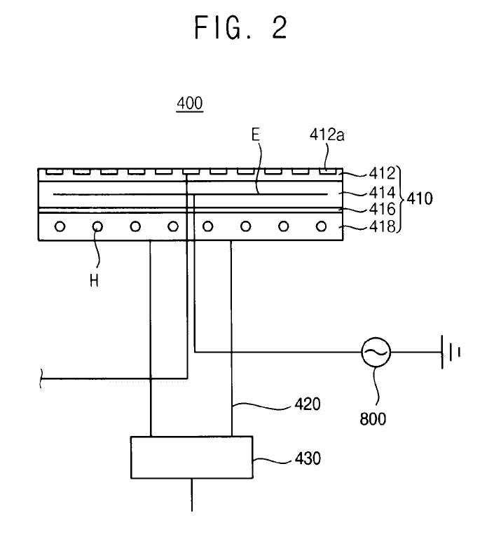

FIG. 2 is a cross-sectional view illustrating the chuck of the PVD apparatus shown in FIG. 1.

Referring to FIG. 2, the chuck 400 may include a support 410 to which the substrate W may be secured, a movable shaft 420 connected to the support 410 and moving and rotating the support 410 and a chuck driver 430 for driving the movable shaft 420.

The support 410 may include a first plate 412 making contact with the substrate W, a second plate 414 including the lower electrode E and a third plate 418 including the heater H. A sheet structure 416 may be further interposed between the second plate 414 and the third plate 418 for increasing the efficiency of heat transfer between the heater H and the substrate W.

A plurality of grooves 412a may be arranged on a surface of the first plate 412, and may function as discharge paths for discharging the residuals of the process gases and the byproducts of the deposition process. Thus, the residuals of the process gases and the byproducts of the deposition process may be gathered into the groove 412a and may be discharged from the depositing chamber 120 through the discharge lines 440. In a modified example embodiment, the byproducts and the process gases discharged via the discharge lines 440 may be purified and recycled in a recycling member R and then may be supplied again into the source tank T.

A plurality of the heaters H may be arranged with uniform intervals in the third plate 418, and may generate heat for uniformly heating the substrate W on the first plate 412. For example, the heater H may include a hot coil and the Joule heat may be generated from the heater H.

When the heaters H may generate heat in the third plate 418, the heat generated from a peripheral group of the heaters H may be radiated into the second space S2 through a side portion of the third plate 418 as well as to the substrate W through a top portion of the third plate 418, while the heat generated from a central group of the heaters H may be just radiated to the substrate W. Thus, the central portion of the substrate W may be heated to a relatively high temperature and the peripheral portion of the substrate W may be heated to a relatively small temperature.

Since the evaporation heat of the phase-changeable material may be relatively small compared with the process temperature of the PVD, the temperature deviation of the substrate W may have great effect on the degree of vaporization of the phase-changeable material, to thereby significantly increase the non-uniformity of the phase-changeable layer on the substrate W.

In present example embodiment, the supplementary heater 600 may generate the additional heat around the substrate W and thus the temperature deviation on the substrate W may be sufficiently reduced and the degree of vaporization of the phase-changeable material may be uniform on the whole surface of the substrate W. Therefore, the phase-changeable material may be deposited onto the substrate W with sufficiently high uniformity no matter how small the evaporation heat of the vaporization of the phase-changeable material and no matter how high the process temperature of the PVD process in the deposition chamber 120.

The lower electrode E may guide the ion particles of the phase-changeable material to vertically move toward the substrate W. For example, the lower electrode E may include at least an electrical electrode that may be built in the second plate 414 and may face the upper electrode of the plasma generator 300 opposite to each other. Therefore, the ion particles of the phase-changeable material may move toward the substrate W in an electrical field between the upper electrode and the lower electrode E.

In a modified example embodiment, a magnet 500 may be arranged over the target member 200 and may force the ion particles of the phase-changeable material to move toward the substrate W in a direction perpendicular to the substrate W. The magnet 500 may include a first magnetic body 520 that may be shaped into a disk and be positioned at a central portion of the magnet 500 and a second magnetic body 540 that may be shaped into a ring enclosing the first magnetic body 520 and be positioned at a peripheral portion of the magnet 500. The first magnetic body 520 may have a first polarity and the second magnetic body 540 may have a second polarity different from the first polarity. The magnetic 500 may rotate with respect to a central axis of the disk-shaped first magnetic body 520 at a constant angular velocity, thus the magnetic field caused by the magnet 500 may be periodically varied.

The density of the magnetic field may be higher at a peripheral portion of the target member 200 rather than the peripheral portion of the substrate W, so that the ion particles of the phase-changeable material may move much better perpendicularly to the substrate W, thereby increasing the uniformity of the deposition. In addition, the ion particles of the phase-changeable material may be uniformly generated from the whole target member 200 due to the rotation of the magnet 500. That is, the erosion of the target member 200 may be uniformly conducted because the magnet may be rotated over the target member 200.

As described above, the ion particles of the phase-changeable material may be forced to move toward the lower electrode E in the electrical field between the upper electrode and the lower electrode E and thus the phase-changeable material may be deposited onto the substrate W.

In case that a pattern structure having a relatively high aspect ratio may be arranged on the substrate W and an opening or a recess of the pattern structure need be filled up with gap-fill materials by the PVD process, the process temperature of the depositing chamber 120 need be sufficiently high due to the characteristics of the PVD process. The process temperature of the substrate W may be increased by the heaters H of the chuck 400 and thus the temperature deviation of the substrate W may occur in the PVD process due to the heat radiation via the sidewall of the chuck 400. The deviation temperature of the substrate W may cause the evaporation difference of the phase-changeable material on the substrate W, thus the phase-changeable layer may be formed non-uniformly on the substrate W.

Particularly, when a memory cell of the phase-changeable memory device may be formed into a multilayer structure by a PVD process using germanium (Ge), tellurium (Te) and antimony (Sb), the process temperature need be increased for improving gap-fill characteristics. However, the temperature deviation of the substrate W may be increased as the process temperature may increase and as a result, the uniformity of the multilayer structure on the whole substrate W may be severely deteriorated as the process temperature may increase.

For those reasons, the supplementary heater 600 may generate additional heat around the substrate W and may reduce the temperature deviation of the substrate W. Accordingly, the uniformity of the phase-changeable layer may be sufficiently improved on the whole substrate W. The supplementary heater 600 may have various configurations in view of the configurations and requirements of the PVD apparatus 1000. For example, the supplementary heater 600 may be arranged in the loading chamber 140 and may additionally heat the peripheral portion of the substrate W under the substrate W. Otherwise, the supplementary heater 600 may be arranged in the depositing chamber 120 and may additionally heat the peripheral portion of the substrate W over the substrate W.

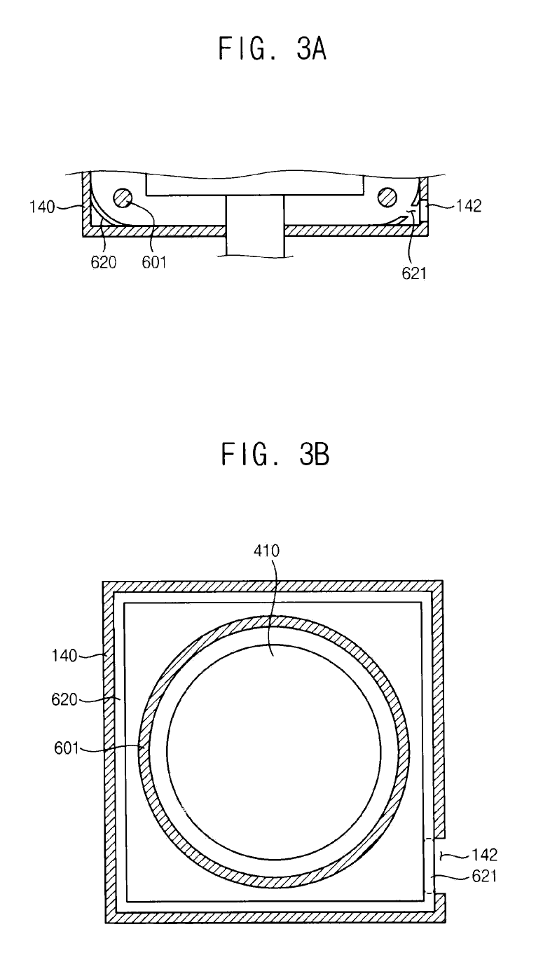

FIG. 3A is a cross-sectional view of an example embodiment of the supplementary heater of the PVD apparatus shown in FIG. 1 and FIG. 3B is a plan view of the example embodiment of the supplementary heater shown in FIG. 3A.

Referring to FIGS. 3A and 3B, the example embodiment 601 of the supplementary heater 600 (hereinafter, the first supplementary heater 601) may be arranged in the loading chamber 140 and may be downwardly spaced apart from a peripheral portion of a bottom surface of the chuck 400. For example, the first supplementary heater 601 may include a ring-shaped electrical lamp surrounding the chuck 400. In another example embodiment, the first supplementary heater 601 may include a ring-shaped tube surrounding the chuck 400 and through which a relatively high temperature fluid may flow.

Since the first supplementary heater 601 may be arranged under the chuck 400 with surrounding the substrate W, the heat generated from the first supplementary heater 601 may be transferred to the substrate W by radiation. Particularly, the first supplementary heater 601 may be arranged under the third plate 418 while being spaced apart from the chuck 400.

For example, the first supplementary heater 601 may be located at a position that may be horizontally spaced apart about 5 cm to about 10 cm from an edge line of the third plate 418 and be vertically lower than the third plate 418. Thus, the chuck 400 may not be directly heated by the first supplementary heater 601 and the substrate W may be heated by the radiant heat from the first supplementary heater 601. Further, the sidewalls and the bottom surface of the deposition chamber 120 may also be heated by the radiant heat of the first supplementary heater 601, so that the temperature of the second space S2 of the depositing chamber 120 may indirectly increase by the first supplementary heater 601.

In a modified example embodiment, a heat shielding member 620 may be further arranged in the loading chamber 140. The heat shielding member 620 may be concavely connected to the sidewall and the bottom surface of the loading chamber 140 and may surround the first space S1, an inner space of the loading chamber 140. Since radiated all directions from the first supplementary heater 601, the radiant heat may also be transferred to the sidewall and bottom surface of the loading chamber 140 as well as the substrate W. Thus, some portion of the radiant heat may be dissipated outward from the loading chamber 140 and may have no effect on the substrate heating. The heat shielding member 620 may prevent or inhibit the radiant heat from being dissipated outward from the loading chamber 140 and thus may increase an inner temperature of the first space S1 of the loading chamber 140.

Particularly, the heat shielding member 620 may have a concave surface with respect to the first space S1 and the radiant heat may be confined in the first space S1. As a result, the temperature of the first space S1 may be more rapidly increased by the heat shielding member 620. In addition, a penetration hole 621 may be provided with the heat shielding member 620 in such a configuration that the second gate 142 may be communicated with the penetration hole 621, so that the substrate W may be loaded into or unloaded from the loading chamber 140 through the heat shielding member 620.

The first supplementary heater 601 may be modified into various shapes and structures.

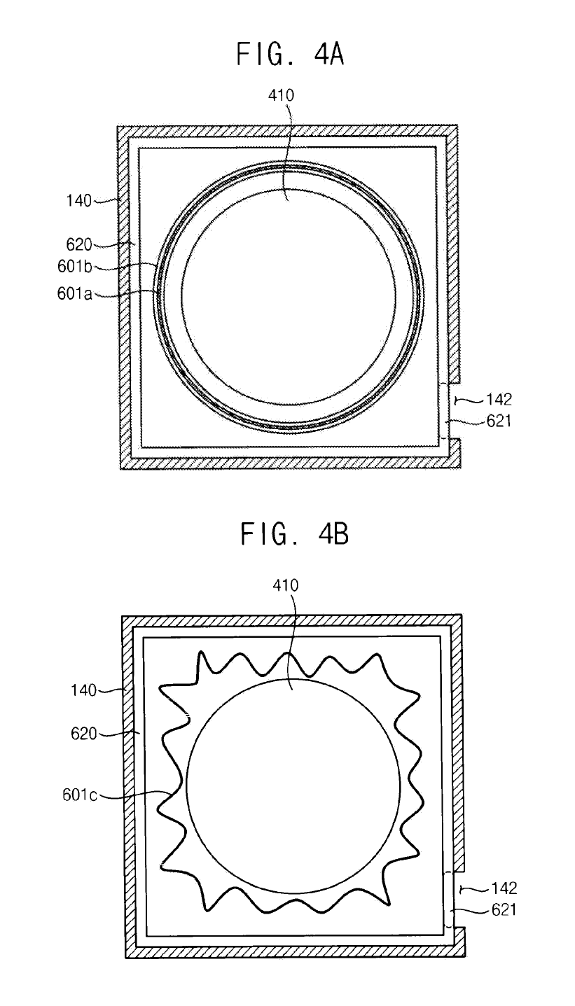

FIGS. 4A and 4B are plan views illustrating the modifications of the first supplementary heater shown in FIGS. 3A and 3B.

As illustrated in FIG. 4A, the first supplementary heater 601 may be modified to include a supplementary chuck 601b surrounding the chuck 400 and an electrical coil 601a built in the supplementary chuck 601b. Thus, when the substrate W may be loaded into or unloaded from the loading chamber 140, the electrical coil 601a may be sufficiently protected from the disturbances caused by the loading/unloading of the substrate W because the electrical coil 601a may be encapsulated in the supplementary chuck 601b.

Otherwise, as illustrated in FIG. 4B, the first supplementary heater 601 may be modified to include an electrical wave coil 601c enclosing the chuck 400. When other inner structures and elements may be arranged in the first space S1 of the loading chamber 140 and thus the first supplementary heater 600 may be interrupted with the inner structures of the loading chamber 140, the first supplementary heater 600 may be modified into the electrical wave coil 601c, thereby preventing or inhibiting the interrupts between the inner structures of the loading chamber 140 and the electrical wave coil 601c. In such a case, a proximal portion of the electrical wave coil 601c may be spaced apart from the chuck 400 in a range of about 5 cm to about 10 cm.

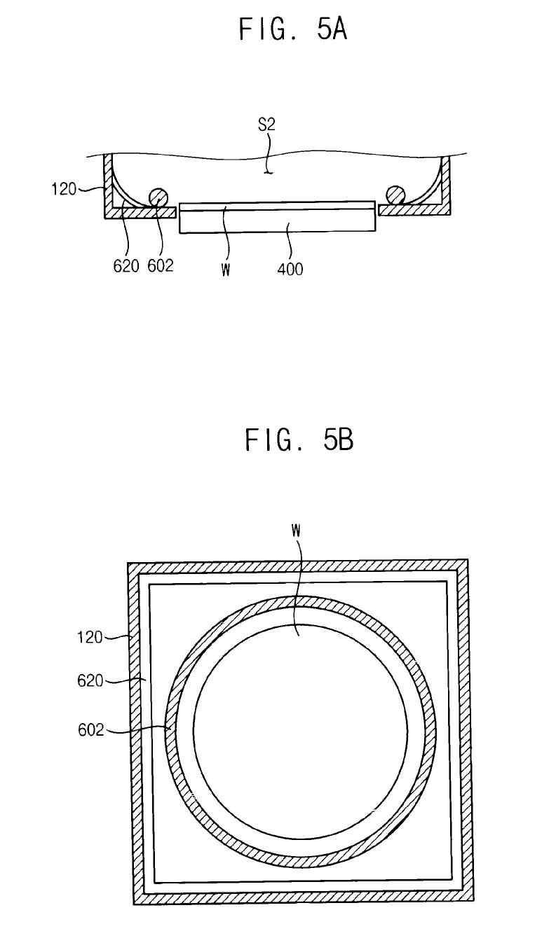

FIG. 5A is a cross-sectional view of an example embodiment of the supplementary heater of the PVD apparatus shown in FIG. 1 and FIG. 5B is a plan view of the example embodiment of the supplementary heater shown in FIG. 5A.

Referring to FIGS. 5A and 5B, the example embodiment 602 of the supplementary heater 600 (hereinafter, the second supplementary heater 602) may be arranged in the depositing chamber 120 and may be upwardly spaced apart from a peripheral portion of a top surface of the chuck 400.

For example, the second supplementary heater 602 may include a ring-shaped electrical lamp surrounding the first plate 412. The second supplementary 602 may be arranged on the bottom surface of the depositing chamber 120 or may be arranged in the second space S2 with being spaced apart from the sidewall and bottom surface of the depositing chamber 120.

Particularly, the second supplementary heater 602 may be spaced apart from the first plate 412 with surrounding the substrate W and the heat generated from the second supplementary heater 602 may be transferred to the substrate W not by a conduction via the chuck 400 but by a radiation in the second space S2. Thus, the temperature deviation of the substrate W may be sufficiently reduced between the central portion and the peripheral portion thereof.

While the present example embodiment discloses the electrical lamp as the second supplementary heater 602, the fluid tube through which the relatively high temperature fluid may flow may also be used as the second supplementary heater 602 as long as the fluid tube may sufficiently endure the process conditions of the depositing chamber 120.

The heat shielding member 620 may be further arranged in the depositing chamber 120 similar to the configurations of the loading chamber 140. The heat shielding member 620 may be concavely connected to the sidewall and the bottom surface of the depositing chamber 120 and may surround the second space S2, i.e., an inner space of the depositing chamber 120. Since radiated all directions from the second supplementary heater 602, the radiant heat may also be transferred to the sidewall and bottom surface of the depositing chamber 120 as well as the substrate W. Thus, some portion of the radiant heat may be dissipated outward from the depositing chamber 120 and may have no effect on the substrate heating. The heat shielding member 620 may prevent or inhibit the radiant heat from being dissipated outward from the depositing chamber 120 and thus may increase an inner temperature of the second space S2 of the depositing chamber 120.

Particularly, when the inner temperature of the second space S2 may be sufficiently high due to the second supplementary heater 602, the residuals of the phase-changeable materials and the byproducts of the deposition may be sufficiently prevented or inhibited from being deposited onto the sidewalls of the depositing chamber 120.

Since the chuck 400 may be located at a lower portion of the depositing chamber 120 and the heat may be continuously generated from the heater H in the chuck 400, the temperature of the lower portion may be generally higher than that of the upper portion of the depositing chamber 120. Therefore, the evaporated phase-changeable material may tend to be extracted or deposited onto the upper portion of the depositing chamber 120 while the phase-changeable material may be evaporated on the substrate W at the lower portion of the depositing chamber 120.

However, when the additional heat may be generated from the second supplementary heater 602 and may be sufficiently prevented or inhibited from dissipating from the depositing chamber 120, the inner temperature of the second space S2 may be sufficiently high and the evaporated phase-changeable material may be sufficiently prevented or inhibited from being extracted or deposited onto the upper portion of the depositing chamber 120. Accordingly, the period of the repair and replacement of the PVD apparatus 1000 may increase and may reduce the maintenance cost of the PVD apparatus 1000.

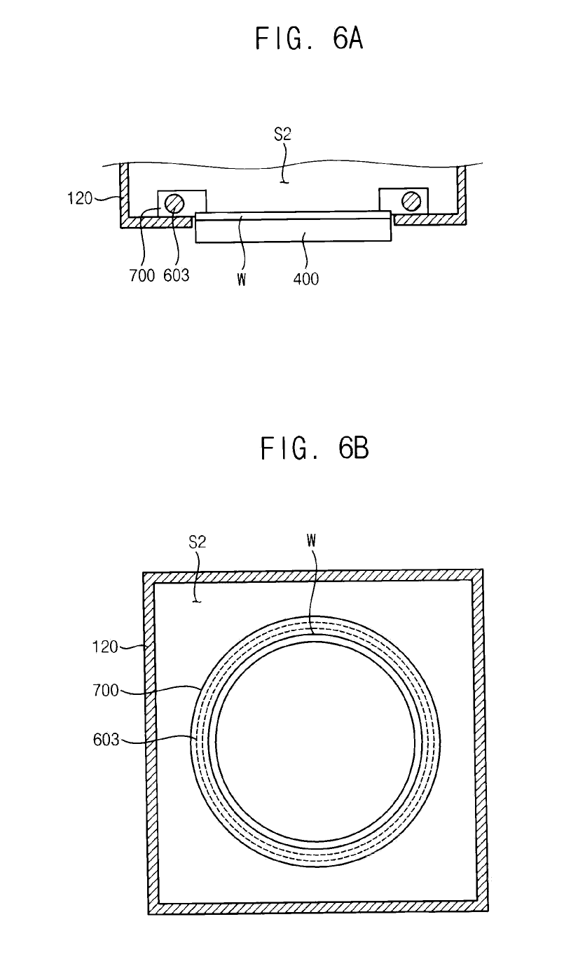

FIG. 6A is a cross-sectional view of an example embodiment of the supplementary heater of the PVD apparatus shown in FIG. 1 and FIG. 6B is a plan view of the example embodiment of the supplementary heater shown in FIG. 6A.

Referring to FIGS. 6A and 6B, a holder 700 for holding the substrate W to the chuck 400 may be further arranged in the depositing chamber 120 and the example embodiment 603 of the supplementary heater 600 (hereinafter, the third supplementary heater 603) may be arranged in the holder 700.

For example, the holder 700 may hold the substrate W to the chuck 400 and the substrate W may be prevented or inhibited from being separated from the chuck 400 in the deposition process. Particularly, the substrate W may be mechanically held to the first plate 412 by the holder 700. The hold 700 may be shaped into a ring of which the outer edge portion may be secured to the bottom surface of the depositing chamber 120 and the inner edge portion may make contact with the substrate W. Thus, an elastic force or a compressive force may be applied to the substrate W by the ring-shaped holder 700 and thus the substrate W may be forced to combine with the first plate 412.

The third supplementary heater 603 may be arranged in the holder 700 and may be shaped into the ring surrounding the substrate W. In the present example embodiment, the third supplementary heater 603 may include an electrical heating body built inside the holder 700 and may be spaced apart from the first plate 412 in a range of about 5 cm to about 10 cm. Therefore, the third supplementary heater 603 may be protected from the deposition conditions of the depositing chamber 120.

A first power source 820 for supplying a power to the supplementary heater 600 and a second power source 830 for supplying an electrical power to the heater H and the electrode E may be arranged around the process chamber 100.

The first power source 820 may be electrically or mechanically connected to the supplementary heater 600 and may transfer the power for generating the additional heat. For example, the first power source 820 may include an electrical power source for generating the Joule heat and a relatively high temperature fluid reservoir from which the relatively high temperature fluid may flow into the supplementary heater 600.

The second power source 830 may include a direct current (DC) power for applying direct currents to the heater H and an alternating current (AC) power for applying a radio frequency (RF) power to the lower electrode E. For example, the second power source 830 may apply the AC power of about 1 KW to the lower electrode E at a frequency of about 13.56 MHz.

A controller 900 may be further provided with the PVD apparatus 1000. The controller 900 may be connected to the process gas supplier 810, the plasma generator 300, the first power source 820 and the second power source 830 and may control the physical vapor deposition process for forming the phase-changeable layer on the substrate W in the process chamber 100.

The loading and unloading of the substrate W, the heating of the substrate W by operation of the heaters H, the generation of the process gas plasma, the generation of the electrical field between the upper and the lower electrodes and the guidance of the ion particles of the phase-changeable material to the substrate W by operation of the magnet 500 may be sequentially and systematically controlled by the controller 900 for forming the phase-changeable layer on the substrate W.

When the evaporation heat of the phase-changeable material may be lower than a reference value, the controller may control to operate the first power source 820 and thus the supplementary heater 600 may generate the additional heat in the process chamber 100. Therefore, the peripheral portion of the substrate W may be additionally heated by the supplementary heater 600 and the temperature deviation of the substrate W may be sufficiently reduced. Therefore, the phase-changeable layer may be uniformly formed on a whole surface of the substrate W.

In addition, the inner temperature of the second space S2 may also be controlled by the supplementary heater 600 for varying the thickness of the phase-changeable layer. When the temperature of the second space S2 may be relatively high, the evaporation of the phase-changeable material may be accelerated on the substrate W and thus the phase-changeable material may be relatively less deposited to the substrate W. Thus, the phase-changeable layer may be formed on the substrate W to a relatively small thickness. Otherwise, when the temperature of the second space S2 may be relatively low, or may be controlled to be under a preset deposition temperature, the evaporation of the phase-changeable material may be relatively less conducted on the substrate W and thus the phase-changeable material may be relatively more deposited to the substrate W. Thus, the phase-changeable layer may be formed on the substrate W to a relatively large thickness.

Particularly, when the temperature of the second space S2 may be controlled to be under the preset deposition temperature corresponding to a melting point of a specific material, the deposition amount of the specific material may increase on the substrate W. when the temperature of the second space S2 may be controlled to be over the preset deposition temperature corresponding to a melting point of a specific material, the deposition amount of the specific material may decrease on the substrate W. Therefore, the composition of the deposited layer on the substrate W may be controlled by varying the temperature of the second space S2 of the deposing chamber 120.

In the present example embodiment, the controller 900 may control the first power source 820 and as a result the supplementary heater 600 to operate in such a way that the temperature of the second space S2 may be in a range of about 200° C. to about 500° C. on condition that the evaporation heat of the phase-changeable material may be below or equal to 200 mJ.

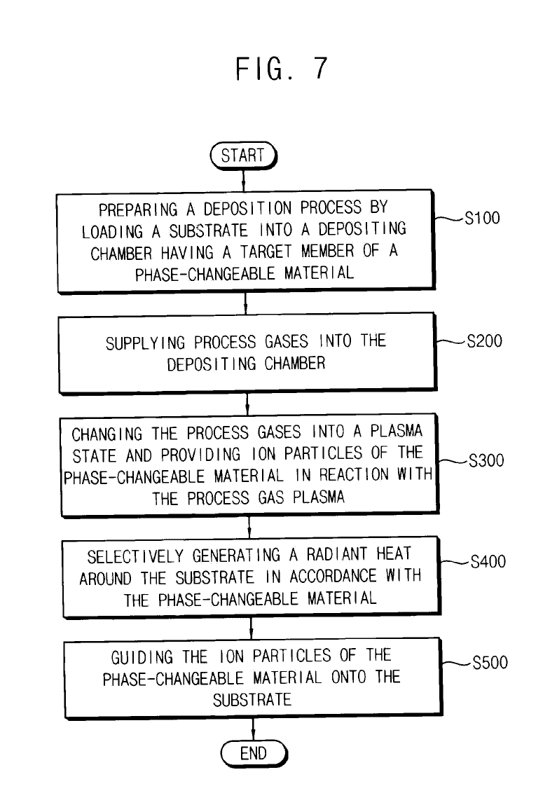

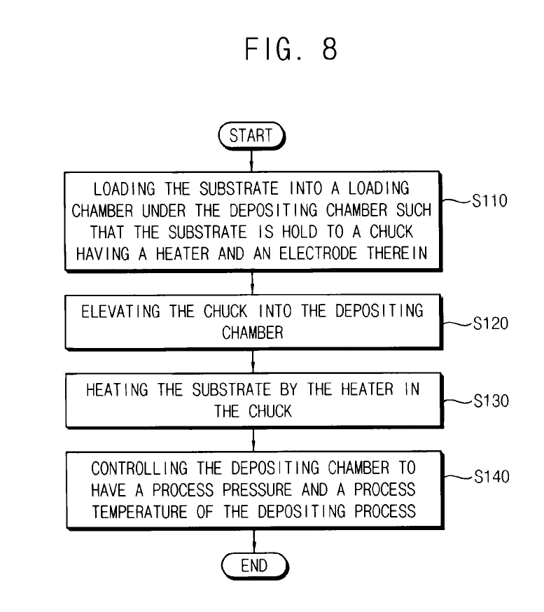

FIG. 7 is a flow chart showing a method of forming a phase-changeable layer on a substrate in the PVD apparatus shown in FIG. 1. FIG. 8 is a flow chart showing the step of preparing the deposition process shown in FIG. 7.

Referring to FIGS. 1, 7 and 8, a deposition process may be prepared by loading a substrate into a depositing chamber having a target member of a phase-changeable material (step S100).

For example, the substrate W may be loaded into the loading chamber 40 under the depositing chamber 120 in such a way that the substrate W may be hold to the chuck 400 having the heaters H and the lower electrodes E therein (step S110).

The substrate W may be drawn out of a POUP (not shown) by a transfer member such as a robot arm and may be loaded onto the first plate 412 of the chuck 400 through the second gate 142 of the loading chamber 140.

Then, the chuck 400 to which the substrate W may be hold may be elevated into the depositing chamber 120, until the substrate W may be positioned in the second space S2 of the depositing chamber 120 (step S120). At first, the movable shaft 420 may move upwards by the chuck driver 430 until the support 410 may be positioned in the second space S2, and then the movable shaft 420 may be rotated by the chuck driver 430. Therefore, the substrate W may be aligned with an aligning mark in the depositing chamber 120. Thereafter, the substrate W may be stably combined to the chuck 400 by the holder 700.

Then, the substrate W may be heated by the heaters H in the chuck 400 (step S130) and the depositing chamber 120 may be controlled to have preliminary process conditions of the PVD process (step S140).

For example, the an inner pressure of the depositing chamber 120 may be controlled to a preliminary pressure using the control pump and an inner temperature of the depositing chamber 120 may be controlled to a preliminary temperature that may be sufficiently ready for the plasma process. In the present example embodiment, the depositing chamber 120 may be under the pressure of about 13 mTorr to about 75 mTorr in the deposition process.

Then, the process gases may be supplied into the depositing chamber 120 from the source tank T via the supply tube 811 (step S200). Thereafter, the process gases may be changed into the plasma state by the plasma generator 300, so that the process gases may be generated into the process gas plasma in the depositing chamber 120 and the ion particles of the phase-changeable material may be provided in the depositing chamber 120 to react with the process gas plasma (step S300).

A relatively high frequency AC power may be applied to the plasma generator 300 and the process gases may be changed into the process gas plasma. The phase-changeable material of the target member 200 may react with the process gas plasma, and the ion particles of the phase-changeable material may be generated from the target member 200 in the second space S2. In such a case, the magnet 500 may be operated together with the plasma generator 300 and thus a magnetic field may be generated around the target member 200 with a sufficient intensity. Thus, the ion particles may be controlled to be distributed around the target member 200 by the magnetic field. Further, the ion particles may be uniformly generated from the target member 200 due to the rotation of the magnet 500, and the target member 200 may be uniformly eroded or consumed in the deposition process.

The supplementary heater 600 may be selectively operated in accordance with the phase-changeable material and the requirements of the deposition process. Thus, the additional heat may be selectively generated in the process chamber 100 and the radiant heat may be transferred to the substrate (step S400). Then, the electrical field may be generated between the upper and the lower electrodes and the ion particles of the phase-changeable material may be guided to the substrate W (step S500).

For example, when the phase-changeable layer may include a composite GST layer including germanium (Ge), antimony (Sb) and tellurium (Te), the deposition amount of the germanium (Ge) and tellurium (Te) may be non-uniform across the substrate W. The evaporation heat of germanium (Ge) and tellurium (Te) may be relatively small than that of antimony (Sb) and thus the deposition amount of germanium (Ge) and tellurium (Te) may be much more sensitive to the process temperature than the antimony (Sb). Accordingly, when the temperature deviation may occur across the substrate W in the deposition process, the deposition amount of germanium (Ge) and tellurium (Te) may be significantly different between the peripheral portion and the central portion of the substrate W. Accordingly, the composition and thickness of the GST layer may be varied across the substrate W due to the differences of the evaporation heat of the materials. In addition, the recent trend of relatively high integration degree of the semiconductor devices may tend to increase the aspect ratio of a GST pattern structure, and thus the deposition process need be performed at a higher deposition temperature for improving the gap-fill characteristics. The temperature deviation of the substrate W may be increased as the deposition temperature may increase in the depositing chamber 120. For those reasons, the composition and thickness of gate structures having the GST pattern structure may be significantly different between the central portion and the peripheral portion of the substrate W due to the differences of the evaporation heat and the relatively high deposition temperature.

In the present example embodiment, when the evaporation heat of the phase-changeable material may be under a reference value and the deposition temperature may be over the reference temperature, the controller 900 may operate the supplementary heater 600 in the process chamber 100 and then the additional heat may be supplied to the peripheral portion of the substrate W as the radiant heat. As a result, the temperature deviation between the central portion and the peripheral portion of the substrate W may be sufficiently reduced in the deposition process, and thus the phase-changeable layer may be formed uniform across the whole surface of the substrate W.

In addition, the inner temperature of the deposition chamber 120 may be controlled by the supplementary heater 600 in the deposition process, thereby controlling the composition and thickness of the GST layer on the substrate W.

In the present example embodiment, the controller 900 may control the first power source 820 and as a result the supplementary heater 600 to operate in such a way that the temperature of the second space S2 may be in a range of about 200° C. to about 500° C. on condition that the evaporation heat of the phase-changeable material may be below or equal to 200 mJ.

Particularly, when the supplementary heater 600 may include an electrical heater, the supplementary heater 600 may be easily controlled just by selectively switching the current on or off, which may facilitate the control of the supplementary heater 600 with ease and rapidity in accordance with the operation conditions of the supplementary heater 600 and may significantly increase the uniformity of the GST layer.

Otherwise, when the supplementary heater 600 may include a fluid tube line through which the relatively high temperature fluid may flow, the supplementary heater 600 may be easily controlled just by regulating the amount of the relatively high temperature fluid. The mass flow of the relatively high temperature fluid may be regulated using a valve system. The heat of the relatively high temperature fluid may be transferred to the peripheral portion of the substrate W from the supplementary heater 600 by a radiation.

According to the example embodiments of the PVD apparatus and a method of forming a phase-changeable layer on a substrate, when the evaporation heat of the phase-changeable material may be relatively small and the deposition temperature for the PVD process may be relatively high, the additional heat may be supplied to the process chamber and thus the temperature deviation of the substrate may be sufficiently reduced in the deposition process. Accordingly, the composition and the thickness of the phase-changeable layer may be sufficiently uniform across the whole surface of the substrate.

In addition, the evaporation amount of the phase-changeable material may be easily controlled just by the controlling the process temperature of the depositing chamber 120, thereby easily controlling the composition and thickness of the phase-changeable layer.

Particularly, when the temperature of the peripheral portion may be lower than that of the central portion of the substrate due to the heat dissipation via the sidewall of the chuck, the gap-fill characteristics may be deteriorated at the peripheral portion rather than the central portion of the substrate and thus process defects such as the voids may be frequently found at the peripheral portion of the substrate. However, the supplementary heater may generate the additional heat in the process chamber and thus the temperature of the peripheral portion of the substrate may be sufficiently increased and the temperature deviation may be reduced on the substrate, thereby improving the gap-fill characteristics in the present PVD apparatus.

While the present inventive concepts disclose the PVD apparatus for depositing the phase-changeable material having a relatively small evaporation heat onto the substrate by a PVD process, any other materials having a small evaporation heat may also be deposited onto the substrate in the present PVD apparatus as long as the ion particles may be guided onto the substrate under the plasma state at a relatively high deposition temperature.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concepts. Accordingly, all such modifications are intended to be included within the scope of the present inventive concepts as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A physical vapor deposition (PVD) apparatus for forming a phase-changeable layer, the PVD apparatus comprising:
a process chamber including,
a loading chamber configured to load a substrate, and
a depositing chamber configured to deposit ion particles of a phase-changeable material onto the substrate;
a target member on an upper portion of the depositing chamber, the target member configured to provide the ion particles of the phase-changeable material, the ion particles reacting with process gases in a plasma state;
a plasma generator configured to generate a process gas plasma from the process gases;
a chuck on a lower portion of the depositing chamber and holding the substrate, the chuck including,
a heater configured to heat the substrate, and
at least one electrode configured to guide the ion particles of the phase-changeable material to the substrate; and
a supplementary heater in the process chamber, the supplementary heater configured to transfer radiant heat around the substrate.

2. The PVD apparatus of claim 1, wherein the supplementary heater is in the loading chamber and spaced apart in a downward vertical direction from a peripheral portion of a bottom surface of the chuck.

3. The PVD apparatus of claim 2, wherein the supplementary heater is a ring-shaped electrical lamp surrounding the chuck.

4. The PVD apparatus of claim 2, wherein the supplementary heater is a ring-shaped tube surrounding the chuck, the ring-shaped tube configured to allow a fluid to flow therethrough.

5. The PVD apparatus of claim 2, further comprising:
a heat shielding member concavely connected to a sidewall and a bottom surface of the loading chamber, the heat shielding member defining a first space inside the loading chamber.

6. The PVD apparatus of claim 1, wherein the supplementary heater is in the depositing chamber and spaced apart in an upward vertical direction from a peripheral portion of a top surface of the chuck.

7. The PVD apparatus of claim 6, wherein the supplementary heater is a ring-shaped electrical lamp surrounding the chuck.

8. The PVD apparatus of claim 6, further comprising:
a heat shielding member concavely connected to a sidewall and a bottom surface of the depositing chamber, the heat shielding member defining a second space inside the depositing chamber.

9. The PVD apparatus of claim 1, further comprising:
a holder secured to a bottom surface of the depositing chamber, the holder configured to secure the substrate to the chuck,
wherein the supplementary heater includes an electrical heating body inside the holder.

10. The PVD apparatus of claim 9, wherein the holder is shaped into a ring covering a peripheral portion of the substrate and the electrical heating body is arranged along the peripheral portion of the substrate in the holder.

11. The PVD apparatus of claim 10, wherein the holder is configured to mechanically connect the substrate to the chuck.

12. The PVD apparatus of claim 1, wherein the phase-changeable material includes one of germanium (Ge), tellurium (Te), antimony (Sb) and combinations thereof.

13. The PVD apparatus of claim 1, further comprising:
a process gas supplier connected to the depositing chamber, the process gas supplier configured to supply the process gases thereto;
a first power source configured to supply power to the supplementary heater;
a second power source configured to supply electrical power to the heater and the at least one electrode; and
a controller connected to the process gas supplier, the plasma generator, the first power source and the second power source, the controller configured to control a physical vapor deposition process for forming the phase-changeable layer on the substrate in the process chamber.

14. The PVD apparatus of claim 13, wherein the controller selectively operates the first power source in accordance with the phase-changeable material in order to selectively operate the supplementary heater in accordance with the phase-changeable material.

15. The PVD apparatus of claim 13, further comprising:
a magnet over the target member, the magnet configured to control a density of the process gas plasma in the depositing chamber.

16. A physical vapor deposition (PVD) apparatus for forming a phase-changeable layer, the PVD apparatus comprising:
a process chamber including a substrate loaded therein;
a target member on an upper portion of the process chamber, the target member configured to deposit ion particles of a phase-changeable material onto the substrate;
an electronic speed controller on a lower portion of the process chamber, the electronic speed controller holding the substrate and configured to guide the ion particles of the phase-changeable material to the substrate; and
a heat dissipating ring in the process chamber, the heat dissipating ring encircling the electronic speed controller and configured to transfer radiant heat around the substrate.

17. The PVD apparatus of claim 16, further comprising:
a heat reflector concavely connected to a sidewall and a bottom surface of the process chamber, the heat reflector defining a space inside the process chamber.

18. The PVD apparatus of claim 16, wherein the heat dissipating ring is spaced apart in a downward vertical direction from a peripheral portion of a bottom surface of the electronic speed controller.

19. The PVD apparatus of claim 16, wherein the heat dissipating ring is spaced apart in an upward vertical direction from a peripheral portion of a top surface of the electronic speed controller.

20. The PVD apparatus of claim 16, further comprising:
a process gas supplier connected to the process chamber, the process gas supplier configured to supply process gases to the process chamber;
a plasma generator configured to generate a process gas plasma from the process gases, the process gas plasma reacting with the ion particles of the phase-changeable material; and
a magnet over the target member, the magnet configured to control a density of the process gas plasma in the process chamber.
